(19) United States
(12) Patent Application Publication
(10) Pub. No.: US 2022/0393699 A1
(43) Pub. Date: Dec. 8, 2022

(54) METHOD FOR COMPRESSING SEQUENTIAL RECORDS OF INTERRELATED DATA FIELDS

(71) Applicant: Circonus, Inc., Fulton, MD (US)

(72) Inventor: Theo Ezell Schlossnagle, Fulton, MD (US)

(21) Appl. No.: 17/886,777

(22) Filed: Aug. 12, 2022

Related U.S. Application Data
(63) Continuation of application No. PCT/US21/17872, filed on Feb. 12, 2021.
(60) Provisional application No. 62/976,774, filed on Feb. 14, 2020.

(51) Int. Cl. H03M 7/30; H03M 7/46

(52) U.S. Cl. CPC H03M 7/6088; H03M 7/46; H03M 7/6011

(57) ABSTRACT

A method for encoding a sequence of records, each record of said sequence of records comprising a plurality of different fields, said different fields being identical for each record of said sequence of records, said method comprising selecting an encoding algorithm for each field of said plurality of fields such that said each field is associated with a selected encoding algorithm; encoding data of said each field using said selected encoding algorithm to determine encoded field data for said each field for said each record; and for said each record, interleaving said encoded field data for said each field to produce an encoded sequence of said records wherein said encoded field data are interleaved for said each record.

### REFERENCE TO RELATED APPLICATION

The Application is based on U.S. Provisional Application No. 62/976,774, filed Feb. 14, 2020, which is hereby incorporated herein by reference.

### REFERENCE TO APPENDIX

Appendix A is pseudocode of one embodiment for executing the method of the claimed invention, and is incorporated herein by reference in its entirety. Although this pseudocode is illustrative of one embodiment of the invention, it should be understood that variations exist, and that the claims should in no way be limited by this pseudocode unless expressly indicated.

### FIELD OF INVENTION

The invention relates, generally, to the compression of data, and more specifically, to the compression of data of sequential records having interrelated fields.

### BACKGROUND

Often data is collected as a sequence of records of interrelated data. For example, data describing an object moving through space may have a number of different fields—e.g., velocity, acceleration, altitude, longitude, latitude, pitch, yawl, time stamp, etc. Each of these fields corresponds to a different measurement relating to the object moving through space. Moreover, these fields are interrelated at a particular time, location, or event. For example, the fields of velocity, acceleration, altitude, longitude, latitude, pitch, and yawl are interrelated at the time of their measurement (i.e., the time stamp). In other words, at a given point in time, each of these fields relates to one another to define the movement of the object at that time. Accordingly, as used herein, the term “record” refers to two or more interrelated fields. In some instances, a record comprises a tuple. (A tuple is a finite ordered list of elements or fields.) It should be understood that the terms “record” and “fields” are intended to be interpreted broadly and carry no other significance beyond what is described herein.

As mentioned above, often data is collected as a sequence of records. The sequence can be based upon time, location, event, or other logical parameter upon which a record is formed. For example, considering again the example above of an object moving through space, the records could be sequential in time based on the time stamp. Accordingly, if the time stamps are in increments of one second, for instance, every second there is a record with data in the aforementioned fields measured at the particular time stamp.

Often there is a need to compress this sequential data. Although there are many well-known compression algorithms/techniques, Applicant recognizes that these known algorithms/techniques are inadequate for sequential records containing multiple interrelated fields.

Specifically, sequential data is often timeseries data, which is a series of data points indexed in time order. Referring back to the example above, each field would correspond to an independent stream of timeseries data—e.g., velocity measurements in time order, longitude measurements in time order, etc. Known run-length algorithms/techniques for compressing/encoding this timeseries data would be performed on each field independently. For example, using these known techniques, the velocity timeseries data would be compressed independently of the longitude timeseries data. Although this serves to compress the data considerably, Applicant recognizes that such compression techniques lose the collation of the fields within a given record.

Therefore, Applicant recognizes the need to compress data of sequential records comprising different fields in a way that does not lose the collation of the different fields within a given record. The present invention fulfills this need among others.

### SUMMARY OF INVENTION

The following presents a simplified summary of the invention in order to provide a basic understanding of some aspects of the invention. This summary is not an extensive overview of the invention. It is not intended to identify key/critical elements of the invention or to delineate the scope of the invention. Its sole purpose is to present some concepts of the invention in a simplified form as a prelude to the more detailed description that is presented later.

Applicants recognize that sequential records containing interrelated fields of data need to be compressed without losing either the interrelationship or collation of the fields. To this end, Applicant has developed an algorithm that compresses sequential records by interleaving independently-encoded fields of data for each record. More specifically, each field within the record has a compression method associated with it, and, as new records are appended to a dataset, the compression works to apply the compression methods (which may be different), interleaving the output into the final compressed form. Therefore, each field may be encoded/compressed independently of the other fields, but, for each record, the fields are interleaved in one sequence of compressed data. This way, the fields of each record are kept together and their collation is not lost. In other words, the fields are no longer separate strings of encoded data, but rather each record becomes a string of interleaved field encoded data.

One aspect of the present invention relates to a method of compressing sequential records having interrelated fields of data. In one embodiment, the method comprises: (a) selecting an encoding algorithm for each field of the plurality of fields such that the each field is associated with a selected encoding algorithm; (b) encoding data of the each field using the selected encoding algorithm to determine encoded field data for the each field for the each record; and (c) for the each record, interleaving the encoded field data for the each field to produce an encoded sequence of the records wherein the encoded field data are interleaved for the each record.

Another aspect of the present invention relates to a system of compressing sequential records having interrelated fields of data. In one embodiment, the system comprises (a) one or more processors for executing a plurality of instructions; (b) a display device in communication with the one or more processors; and (c) a storage device in communication with the one or more processors, the storage device holding the plurality of instructions, the plurality of instructions including instructions for: (i) selecting an encoding algorithm for each field of the plurality of fields such that the each field is associated with a selected encoding algorithm; (ii) encoding data of the each field using the selected encoding algorithm to determine encoded field data for the each field for the each record; and (iii) for the each record, interleaving the encoded field data for the each field to produce an encoded sequence of the records wherein the encoded field data are interleaved for the each record.

Yet another aspect of the present invention relates to a non-transitory computer-readable medium for instructing a computer to compress sequential records having interrelated fields of data. In one embodiment, the computer-readable medium comprises: (a) selecting an encoding algorithm for each field of the plurality of fields such that the each field is associated with a selected encoding algorithm; (b) encoding data of the each field using the selected encoding algorithm to determine encoded field data for the each field for the each record; and (c) for the each record, interleaving the encoded field data for the each field to produce an encoded sequence of the records wherein the encoded field data are interleaved for the each record.

### BRIEF DESCRIPTION OF FIGURES

FIG. 1 depicts an example computer processing system that may be used in implementing an embodiment of the present invention.

### DETAILED DESCRIPTION

In one embodiment, the invention relates to a method for encoding a sequence of records, each record of the sequence of records comprising a plurality of different fields, the method comprising: (a) selecting an encoding algorithm for each field of the plurality of fields such that the each field is associated with a selected encoding algorithm; (b) encoding data of the each field using the selected encoding algorithm to determine encoded field data for the each field for the each record; and (c) for the each record, interleaving the encoded field data for the each field to produce an encoded sequence of the records, wherein the encoded field data are interleaved for the each record. These steps, along with selected alternative embodiments, are described in greater detail below.

An important feature of the present invention is the interleaving of encoded field data for each record. As each record arrives to be appended to the compressed data, each field is considered, compressed independently and then encoded (i.e. interleaved) into the compressed result. By interleaving the encoded field data for each record, the interrelationship of the field data is maintained by virtue of the interrelated fields being proximate to one another. For example, assuming each record [ ] has the same fields in the same order—e.g. ABCD—then the encoded data is [A′B′C′D′][A′B′C′D′][A′B′C′D′][A′B′C′D′][A′B′C′D′] . . . . Thus, when the data is unpacked, interrelated field data are proximate to each other. Keeping interrelated field data proximate is important because of the way hierarchical computer memory works. For examples, a user can load an entire record into an L1 cache and work with it without more expensive subsequent memory accesses to L2 or higher.

Interleaving the encoded field data can be performed in various ways. In one embodiment, the interleaving uses a bit packing to minimize storage. Below is one example which describes the mechanics of interleaving encoded field data derived from different compression techniques based on reasonable presumed varbit function bit encoding lengths.

Assume a series of records with the following fields:
timestamp (64 bit integer)
Temperature (32 bit IEEE float)
Humidity (32 bit integer)

Assume the following 4 records:
1000, 78.34, 57%
1010, 78.21, 55%
1020, 78.15, 55%
1030, 78.10, 54%

Applying the delta-of-delta+varbit run-length compression to the two integer fields and xor+varbit to the float field:
1000 . . . 78.34 . . . 57
Varbit(1010-1000) Varbit(78.23 XOR 78.21) . . . Varbit(55-57)
Varbit((1020-1010)-(1010-1000)) Varbit(78.21 XOR 78.15) . . . Varbit((55-55)-(55-57))
Varbit((1030-1020)-(1020-1010)) Varbit(78.15 XOR 78.10) . . . Varbit((54-55)-(55-55))

Therefore, the first record is encoded to 64 bits+32 bits+32 bits; the second record is encoded to 7 bits+14 bits+7 bits; the third is encoded to: 1 bit+15 bits+7 bits; and the fourth is encoded to 1 bit+14 bits+7 bits. Thus, the coded series would be 128+28+23+22=201 bits, which amounts to just 26 bytes (with 7 bits of the last byte unused). Therefore, using the bit packing when interleaving the fields reduces considerably the bits used.

In one embodiment, the sequence of records have uniformly-structured fields. In other words, each record of the sequence of records has the same fields in the same order. Having records of uniformly structured fields simplifies the encoding/interleaving and eliminates the need for additional/complex algorithms to compensate for variation in fields among records.

In one embodiment, two or more of the fields of a record may have different datatypes. For example, the datatypes may comprise integers, floating-point numbers, fixed-point numbers, character, Boolean, money, or date, just to name a few. For example, a “timed position” recode may be expressed: {timestamp unsigned 64 bit integer, longitude IEEE double, latitude IEEE double}.

As is known, the type of encoding/compression used tends to depend on the datatype. Accordingly, in one embodiment, the system of the present invention comprises a library of different encoding algorithms which can be selected for a particular field to optimize the encoding of the datatype of that field. Examples of different encoding algorithms include varbit, varbitLT, varbit L, XOR, delta of delta, just to name a few. Referring back to the “timed position” example above, the compression algorithm for the timestamp field might be delta of delta using varbitLT and the longitude and latitude fields might be compressed using XOR with varbitL.

Selecting the encoding algorithm for each field may be performed in different ways. For example, in one embodiment, the selection is done manually, in which a user determines which algorithm encodes the data of a particular field most effectively and then assigns that algorithm to that field. One of skill in the art will understand how to determine the optimum algorithm for a datatype. For example, in one embodiment, this can be done by running different algorithms on a portion of the data from a particular field to determine which algorithm performs the best or otherwise provides suitable results. In another embodiment, one of skill in the art may be able to determine a suitable algorithm by observing the datatype.

In another embodiment, selecting the algorithm for a particular field is performed automatically by the system. Again, as described above, there are different ways for doing this. For example, in one embodiment, the system, comprises an optimizer for testing different algorithms on the data of a particular field to determine which algorithm performs the best or otherwise meets a threshold level of suitability.

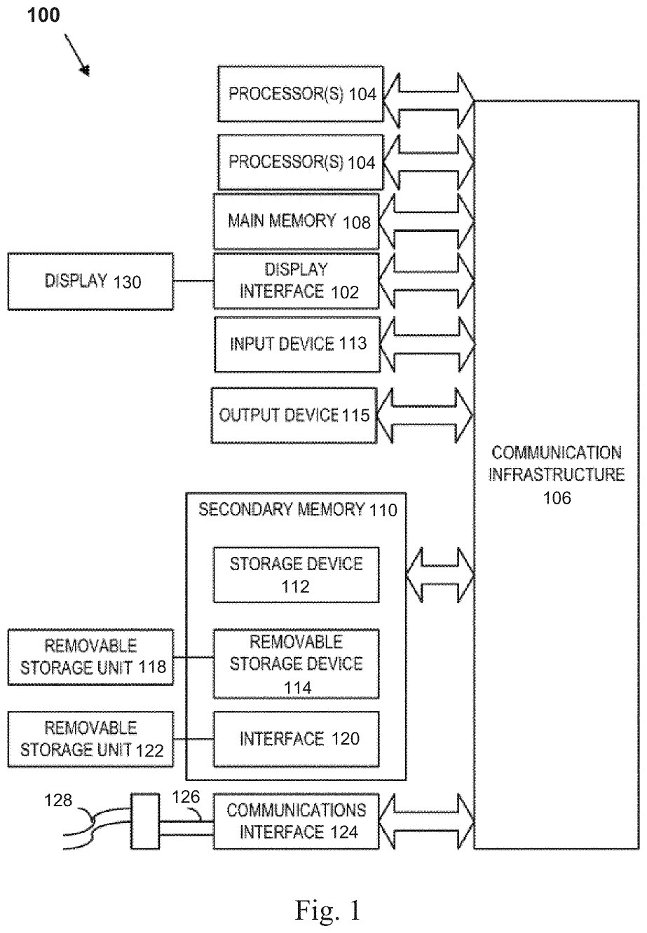

FIG. 1 depicts an example computer system that may be used in implementing an illustrative embodiment of the present invention. Specifically, FIG. 1 depicts an illustrative embodiment of a computer system 100 that may be used in computing devices such as, e.g., but not limited to, standalone, client/server devices, cloud-based/cloud-service, or system controllers. FIG. 1 depicts an illustrative embodiment of a computer system that may be used as client device, a server device, a controller, etc. The present invention (or any part(s) or function(s) thereof) may be implemented using hardware, software, firmware, or a combination thereof and may be implemented in one or more computer systems or other processing systems. In fact, in one illustrative embodiment, the invention may be directed toward one or more computer systems capable of carrying out the functionality described herein. An example of a computer system 100 is shown in FIG. 1, depicting an illustrative embodiment of a block diagram of an illustrative computer system useful for implementing the present invention. Specifically, FIG. 1 illustrates an example computer 100, which in an illustrative embodiment may be, e.g., (but not limited to) a personal computer (PC) system running an operating system such as, e.g., (but not limited to) MICROSOFT® WINDOWS® NT/98/2000/XP/Vista/Windows 7/Windows 8, etc. available from MICROSOFT® Corporation of Redmond, Wash., U.S.A. or an Apple computer executing MAC® OS or iOS from Apple® of Cupertine, Calif., U.S.A. or a smartphone running iOS, Android, or Windows mobile, for example. However, the invention is not limited to these platforms. Instead, the invention may be implemented on any appropriate computer system running any appropriate operating system. In one illustrative embodiment, the present invention may be implemented on a computer system operating as discussed herein. An illustrative computer system, computer 100 is shown in FIG. 1. Other components of the invention, such as, e.g., (but not limited to) a computing device, a communications device, a telephone, a personal digital assistant (PDA), an iPhone, a 3G/4G wireless device, a wireless device, a personal computer (PC), a handheld PC, a laptop computer, a smart phone, a mobile device, a netbook, a handheld device, a portable device, an interactive television device (iTV), a digital video recorder (DVR), client workstations, thin clients, thick clients, fat clients, proxy servers, network communication servers, remote access devices, client computers, server computers, peer-to-peer devices, routers, web servers, data, media, audio, video, telephony or streaming technology servers, etc., may also be implemented using a computer such as that shown in FIG. 1. In an illustrative embodiment, services may be provided on demand using, e.g., an interactive television device (iTV), a video on demand system (VOD), via a digital video recorder (DVR), and/or other on demand viewing system. Computer system 100 may be used to implement the network and components as described above.

The computer system 100 may include one or more processors, such as, e.g., but not limited to, processor(s) 104. The processor(s) 104 may be connected to a communication infrastructure 106 (e.g., but not limited to, a communications bus, cross-over bar, interconnect, or network, etc.). Processor 104 may include any type of processor, microprocessor, or processing logic that may interpret and execute instructions (e.g., for example, a field programmable gate array (FPGA)). Processor 104 may comprise a single device (e.g., for example, a single core) and/or a group of devices (e.g., multi-core). The processor 104 may include logic configured to execute computer-executable instructions configured to implement one or more embodiments. The instructions may reside in main memory 108 or secondary memory 110. Processors 104 may also include multiple independent cores, such as a dual-core processor or a multi-core processor. Processors 104 may also include one or more graphics processing units (GPU) which may be in the form of a dedicated graphics card, an integrated graphics solution, and/or a hybrid graphics solution. Various illustrative software embodiments may be described in terms of this illustrative computer system. After reading this description, it will become apparent to a person skilled in the relevant art(s) how to implement the invention and/or parts of the invention using other computer systems and/or architectures.

Computer system 100 may include a display interface 102 (e.g., the HMI) that may forward, e.g., but not limited to, graphics, text, and other data, etc., from the communication infrastructure 106 (or from a frame buffer, etc., not shown) for display on the display unit 101. The display unit 101 may be, for example, a television, a computer monitor, a touch sensitive display device, or a mobile phone screen. The output may also be provided as sound through a speaker.

The computer system 100 may also include, e.g., but is not limited to, a main memory 108, random access memory (RAM), and a secondary memory 110, etc. Main memory 108, random access memory (RAM), and a secondary memory 110, etc., may be a computer-readable medium that may be configured to store instructions configured to implement one or more embodiments and may comprise a random-access memory (RAM) that may include RAM devices, such as Dynamic RAM (DRAM) devices, flash memory devices, Static RAM (SRAM) devices, etc.

The secondary memory 110 may include, for example, (but is not limited to) a hard disk drive 112 and/or a removable storage drive 114, representing a floppy diskette drive, a magnetic tape drive, an optical disk drive, a compact disk drive CD-ROM, flash memory, etc. The removable storage drive 114 may, e.g., but is not limited to, read from and/or write to a removable storage unit 118 in a well-known manner. Removable storage unit 118, also called a program storage device or a computer program product, may represent, e.g., but is not limited to, a floppy disk, magnetic tape, optical disk, compact disk, etc. which may be read from and written to removable storage drive 114. As will be appreciated, the removable storage unit 118 may include a computer usable storage medium having stored therein computer software and/or data.

In alternative illustrative embodiments, secondary memory 110 may include other similar devices for allowing computer programs or other instructions to be loaded into computer system 100. Such devices may include, for example, a removable storage unit 122 and an interface 120. Examples of such may include a program cartridge and cartridge interface (such as, e.g., but not limited to, those found in video game devices), a removable memory chip (such as, e.g., but not limited to, an erasable programmable read only memory (EPROM), or programmable read only memory (PROM) and associated socket, and other removable storage units 122 and interfaces 120, which may allow software and data to be transferred from the removable storage unit 122 to computer system 100.

Computer 100 may also include an input device 103 which may include any mechanism or combination of mechanisms that may permit information to be input into computer system 100 from, e.g., a user or operator. Input device 103 may include logic configured to receive information for computer system 100 from, e.g. a user or operator. Examples of input device 103 may include, e.g., but not limited to, a mouse, pen-based pointing device, or other pointing device such as a digitizer, a touch sensitive display device, and/or a keyboard or other data entry device (none of which are labeled). Other input devices 103 may include, e.g., but not limited to, a biometric input device, a video source, an audio source, a microphone, a web cam, a video camera, and/or other camera.

Computer 100 may also include output devices 115 which may include any mechanism or combination of mechanisms that may output information from computer system 100. Output device 115 may include logic configured to output information from computer system 100. Embodiments of output device 115 may include, e.g., but not limited to, display 101, and display interface 102, including displays, printers, speakers, cathode ray tubes (CRTs), plasma displays, light-emitting diode (LED) displays, liquid crystal displays (LCDs), printers, vacuum fluorescent displays (VFDs), surface-conduction electron-emitter displays (SEDs), field emission displays (FEDs), etc. Computer 100 may include input/output (I/O) devices such as, e.g., (but not limited to) input device 103, communications interface 124, connection 128 and communications path 126, etc. These devices may include, e.g., but are not limited to, a network interface card, onboard network interface components, and/or modems.

Communications interface 124 may allow software and data to be transferred between computer system 100 and external devices or other computer systems. Computer system 100 may connect to other devices or computer systems via wired or wireless connections. Wireless connections may include, for example, WiFi, satellite, mobile connections using, for example, TCP/IP, 802.15.4, high rate WPAN, low rate WPAN, 61oWPAN, ISA100.11a, 802.11.1, WiFi, 3G, WiMAX, 4G and/or other communication protocols.

In this document, the terms “computer program medium” and “computer readable medium” may be used to generally refer to media such as, e.g., but not limited to, removable storage drive 114, a hard disk installed in hard disk drive 112, flash memories, removable discs, non-removable discs, etc. In addition, it should be noted that various electromagnetic radiation, such as wireless communication, electrical communication carried over an electrically conductive wire (e.g., but not limited to twisted pair, CATS, etc.) or an optical medium (e.g., but not limited to, optical fiber) and the like may be encoded to carry computer-executable instructions and/or computer data that embodiments of the invention on e.g., a communication network. These computer program products may provide software to computer system 100. It should be noted that a computer-readable medium that comprises computer-executable instructions for execution in a processor may be configured to store various embodiments of the present invention. References to “one embodiment,” “an embodiment,” “example embodiment,” “various embodiments,” etc., may indicate that the embodiment(s) of the invention so described may include a particular feature, structure, or characteristic, but not every embodiment necessarily includes the particular feature, structure, or characteristic.

Having thus described a few particular embodiments of the invention, various alterations, modifications, and improvements will readily occur to those skilled in the art. Such alterations, modifications, and improvements as are made obvious by this disclosure are intended to be part of this description though not expressly stated herein, and are intended to be within the spirit and scope of the invention. Accordingly, the foregoing description is by way of example only, and not limiting. The invention is limited only as defined in the following claims and equivalents thereto.

What is claimed is:

1. A method for encoding a sequence of records, each record of said sequence of records comprising a plurality of different fields, said different fields being identical for each record of said sequence of records, said method comprising:
selecting an encoding algorithm for each field of said plurality of fields such that said each field is associated with a selected encoding algorithm;
encoding data of said each field using said selected encoding algorithm to determine encoded field data for said each field for said each record; and
for said each record, interleaving said encoded field data for said each field to produce an encoded sequence of said records wherein said encoded field data are interleaved for said each record.

2. The method of claim 1, wherein said plurality of different fields comprises fields having different data types.

3. The method of claim 2, wherein said different data types comprise at least two of integers, floating-point numbers, fixed-point numbers, character, Boolean, money, or date.

4. The method of claim 1, wherein said each record comprises a tuple.

5. The method of claim 4, wherein said each record comprises different measurements of an event at a given time or location, and said plurality of different fields of said each record comprises said different measurements at said given time or said location.

6. The method of claim 5, wherein said each record comprises said measurements at a given time.

7. The method of claim 6, wherein said each record is a record of an object in motion.

8. The method of claim 7, wherein said different measurements comprises at least two or more of velocity, yawl, pitch, latitude, longitude, and time stamp.

9. The method of claim 1, wherein said plurality of different fields is timeseries data.

10. The method of claim 9, wherein said selected encoding algorithm is a run-length algorithm.

11. The method of claim 10, wherein said encoding algorithms comprise at least two of varbit, varbitLT, varbit L, XOR, or delta of delta.

12. The method of claim 1, wherein said selecting a run-length encoding algorithm is performed automatically.

13. The method of claim 12, wherein said selecting a run-length encoding algorithm is performed empirically using an optimizer.

14. The method for encoding timeseries data of claim 13, wherein said selecting a run-length encoding algorithm is performed by testing different run-length encoding algorithms on a portion of said different data types to optimize run-length encoding of said each of said plurality of different data types.

15. A system for constructing histograms comprising:
one or more processors for executing a plurality of instructions;
a display device in communication with the one or more processors; and
a storage device in communication with the one or more processors, the storage device holding the plurality of instructions, the plurality of instructions including instructions for:
selecting an encoding algorithm for each field of said plurality of fields such that said each field is associated with a selected encoding algorithm;
encoding data of said each field using said selected encoding algorithm to determine encoded field data for said each field for said each record; and
for said each record, interleaving said encoded field data for said each field to produce an encoded sequence of said records wherein said encoded field data are interleaved for said each record.

16. A non-transitory computer-readable medium comprising instructions, which when executed by one or more processors causes said one or more processors to perform the steps comprising:
selecting an encoding algorithm for each field of said plurality of fields such that said each field is associated with a selected encoding algorithm;
encoding data of said each field using said selected encoding algorithm to determine encoded field data for said each field for said each record; and
for said each record, interleaving said encoded field data for said each field to produce an encoded sequence of said records wherein said encoded field data are interleaved for said each record.
